(19) United States
(12) Patent Application Publication
(10) Pub. No.: US 2019/0279914 A1
(43) Pub. Date: Sep. 12, 2019

(54) REGION OF INTEREST AND PATTERN OF INTEREST GENERATION FOR CRITICAL DIMENSION MEASUREMENT

(71) Applicant: KLA-TENCOR CORPORATION, Milpitas, CA (US)

(72) Inventors: Jagdish Chandra Saraswatula, Puttaparthi (IN); Hari Pathangi Sriraman, Chennai (IN); Arpit Yati, Lucknow (IN)

(21) Appl. No.: 16/041,207

(22) Filed: Jul. 20, 2018

Related U.S. Application Data
(60) Provisional application No. 62/662,150, filed on Apr. 24, 2018.
(60) Provisional application No. 62/678,666, filed on May 31, 2018.

(30) Foreign Application Priority Data
Mar. 9, 2018 (IN) 201841008799

(51) Int. Cl. H01L 21/66; G01N 23/2251; H01L 21/67

(52) U.S. Cl. CPC H01L 22/12; G01N 23/2251; H01J 37/28; G01N 2223/6116; H01L 21/67288

(57) ABSTRACT

Processes to generate regions of interest for critical dimension uniformity measurement are disclosed. A pattern description based on historical data or a coordinate may be used as input. A pattern of interest can be determined, and then a region of interest can be determined. Instructions can be sent to a wafer inspection tool to image the region of interest on the semiconductor wafer.

### CROSS-REFERENCE TO RELATED APPLICATIONS

This application claims priority to the patent application filed Mar. 9, 2018 and assigned Indian App. No. 201841008799, the provisional patent application filed Apr. 24, 2018 and assigned U.S. App. No. 62/662,150, and the provisional patent application filed May 31, 2018 and assigned U.S. App. No. 62/678,666, the disclosures of which are hereby incorporated by reference.

### FIELD OF THE DISCLOSURE

This disclosure relates to inspection of semiconductor wafers.

### BACKGROUND OF THE DISCLOSURE

Evolution of the semiconductor manufacturing industry is placing ever greater demands on yield management and, in particular, on metrology and inspection systems. Critical dimensions continue to shrink. Economics is driving the industry to decrease the time for achieving high-yield, high-value production. Minimizing the total time from detecting a yield problem to fixing it determines the return-on-investment for a semiconductor manufacturer.

Fabricating semiconductor devices such as logic and memory devices typically includes processing a substrate such as a semiconductor wafer using a large number of semiconductor fabrication processes to form various features and multiple levels of the semiconductor devices. For example, lithography is a semiconductor fabrication process that involves transferring a pattern from a reticle to a resist arranged on a semiconductor wafer. Additional examples of semiconductor fabrication processes include, but are not limited to, chemical-mechanical polishing (CMP), etch, deposition, and ion implantation. Multiple semiconductor devices may be fabricated in an arrangement on a single semiconductor wafer and then separated into individual semiconductor devices.

Inspection processes are used at various steps during a semiconductor manufacturing process to detect defects on wafers to promote higher yield in the manufacturing process and, thus, higher profits. Inspection has always been an important part of fabricating semiconductor devices such as integrated circuits (ICs). However, as the dimensions of semiconductor devices decrease, inspection becomes even more important to the successful manufacture of acceptable semiconductor devices because smaller defects can cause the devices to fail. For instance, as the dimensions of semiconductor devices decrease, detection of defects of decreasing size has become necessary since even relatively small defects may cause unwanted aberrations in the semiconductor devices.

As design rules shrink, however, semiconductor manufacturing processes may be operating closer to the limitation on the performance capability of the processes. In addition, smaller defects can have an impact on the electrical parameters of the device as the design rules shrink, which drives more sensitive inspections. As design rules shrink, the population of potentially yield-relevant defects detected by inspection grows dramatically, and the population of nuisance defects detected by inspection also increases dramatically. Therefore, more and more defects may be detected on the wafers, and correcting the processes to eliminate all of the defects may be difficult and expensive. Determining which of the defects actually have an effect on the electrical parameters of the devices and the yield may allow process control methods to be focused on those defects while largely ignoring others. Furthermore, at smaller design rules, process-induced failures may, in some cases, tend to be systematic. That is, process-induced failures tend to fail at predetermined design patterns often repeated many times within the design. Elimination of spatially-systematic, electrically-relevant defects can be important because eliminating such defects can have an impact on yield.

As features sizes of semiconductor devices continue to shrink, a minimum feature size that may be fabricated may often be limited by the performance characteristics of a semiconductor fabrication process. Examples of performance characteristics of a semiconductor fabrication process include, but are not limited to, resolution capability, across chip variations, and across wafer variations. In optical lithography, for example, performance characteristics such as resolution capability of a lithography process may be limited by the quality of the photoresist application, the performance of the photoresist material, the performance of the exposure tool, and the wavelength of light used to expose the photoresist. The ability to resolve a minimum feature size, however, also may be strongly dependent on other critical parameters of the lithography process such as a temperature of a post-exposure bake process and an exposure dose of an exposure process. As such, controlling the parameters of processes that may be critical to the resolution capability of a semiconductor fabrication process such as a lithography process is becoming increasingly important to the successful fabrication of semiconductor devices.

Critical dimension (CD) is one of the features that is measured during inspection. A CD may include a lateral dimension of a feature defined in a direction substantially parallel to an upper surface of the semiconductor wafer, such as a width of a feature on the semiconductor wafer. Therefore, a CD may be generally defined as the lateral dimension of a feature when viewed in cross section such as a width of a gate or interconnect or such as a diameter of a hole or via. A CD of a feature also may include a lateral dimension of a feature defined in a direction substantially perpendicular to an upper surface of the semiconductor wafer, such as a height of a feature on the semiconductor wafer.

A CD also may include a sidewall angle of a feature. A sidewall angle may be generally defined as an angle of a side (or lateral) surface of a feature with respect to an upper surface of the semiconductor wafer. In this manner, a feature having a substantially uniform width across a height of the feature may have sidewall angle of approximately 90°. Features of a semiconductor device that have a substantially uniform width across a height of the features may be formed relatively closely together thereby increasing device density of the semiconductor device. In addition, such a device may have relatively predictable and substantially uniform electrical properties. A feature having a tapered profile or non-uniform width across a height of the feature may have sidewall angle of less than approximately 90°. A tapered profile may be desired if a layer may be formed upon the feature. For example, a tapered profile may reduce the formation of voids within the layer formed upon the feature.

A CD also can include line edge roughness (LER) measurements. Multiple measurements can be taken and averaged to determine LER.

Critical dimension uniformity (CDU) measurement of physical design entities on the wafer helps ascertain the optimal performance of a very-large-scale integration (VLSI) chip. The CD variation across the chip and the wafer are microscopic indicators of macroscopic phenomena like resistance, gate current, or parasitic effects. CD also helps a semiconductor manufacturer understand the impact of various process parameters like photolithography, etch, or reticle enhancement techniques (RET) with regard to varying design density on the wafer. However, CD measurement is made based on (x,y) coordinate locations provided by a semiconductor manufacturer in consultation with internal teams that may include device engineers, lithography/optical proximity correction (OPC) teams, and other module teams.

Thus, the current technique to make CD measurements is based on previous experience or knowledge of process or device inflections. The semiconductor manufacturer typically provides a set of coordinates and the CD of the structure polygons corresponding to those locations is measured. The process is manual, which means it is subject to errors or can be based on subjective assessments. Apart from being manual, the process of measurement creates an acute dependency on semiconductor manufacturer inputs, which can impact throughput. The criteria behind the selection process for measurement sites relies heavily on previous knowledge of process or device inflections, which means that new failure modes are often not captured in advance.

Therefore, improvements to CD measurement are needed.

### BRIEF SUMMARY OF THE DISCLOSURE

A method is provided in a first embodiment. Using a processor, a pattern description is defined based on historical data. The historical data includes failure cases. The pattern is defined in vectorized image manipulation scripting. Using the processor, a pattern of interest on a semiconductor wafer based on polygons in the historical data is determined. Using the processor, a region of interest disposed in the pattern of interest on a semiconductor wafer that satisfies the pattern description is determined. The region of interest on the semiconductor wafer is imaged using a wafer inspection tool, such as a scanning electron microscope.

The pattern of interest may be defined in Standard Verification Rule Format.

The method can further include searching for instances of the pattern of interest on the semiconductor wafer.

A computer program product comprising a non-transitory computer readable storage medium having a computer readable program embodied therewith also is disclosed. The computer readable program can be configured to carry out the method of the first embodiment.

A method is provided in a second embodiment. A coordinate on a design image that includes a defect is received at a processor. Using the processor, boundaries of a window that is placed around the coordinate are determined. The window includes a pattern of interest. The pattern of interest is defined in vectorized image manipulation scripting. Using the processor, a region of interest in the window is determined based on site information. The region of interest uses a design scripting language. The region of interest on the semiconductor wafer is imaged using a wafer inspection tool, such as a scanning electron microscope. The region of interest can be disposed in the pattern of interest.

A coordinate in the design image can be converted to the coordinate in a wafer coordinate system using the processor.

The pattern of interest can be defined by the boundaries of the window.

The method can include searching for instances of the pattern of interest on the semiconductor wafer.

A computer program product comprising a non-transitory computer readable storage medium having a computer readable program embodied therewith also is disclosed. The computer readable program can be configured to carry out the method of the second embodiment.

A system is provided in a third embodiment. The system includes a wafer inspection tool configured to generate images of a wafer and a processor in electronic communication with the wafer inspection tool. The wafer inspection tool includes an energy source that directs energy at a surface of a semiconductor wafer and a detector. For example, the wafer inspection tool may be a scanning electron microscope. The processor is configured to determine both a pattern of interest and a region of interest on the semiconductor wafer. The pattern of interest is defined in vectorized image manipulation scripting. The processor also is configured to send instructions to the wafer inspection tool to image the region of interest on the semiconductor wafer. The region of interest may be disposed in the pattern of interest on the wafer.

In an instance, the processor is configured to define a pattern description based on historical data, determine the pattern of interest based on polygons in the historical data, and define the region of interest such that the region of interest satisfies the pattern description. The historical data includes failure cases.

In another instance, the processor is configured to receive a coordinate on a design image for the semiconductor wafer, determine boundaries of a window that is placed around the coordinate, and determine a region of interest in the window based on site information. The window includes the pattern of interest. The region of interest is defined using a design scripting language. The processor may be further configured to convert the coordinate in the design image to a coordinate in a wafer coordinate system. The pattern of interest can be defined by the boundaries of the window.

In yet another instance, the processor is further configured to find instances of the pattern of interest on the semiconductor wafer.

### DESCRIPTION OF THE DRAWINGS

For a fuller understanding of the nature and objects of the disclosure, reference should be made to the following detailed description taken in conjunction with the accompanying drawings, in which:

FIG. 1 is a flowchart of a first embodiment of a method in accordance with the present disclosure;

FIG. 2 is an exemplary diagram showing a pattern that satisfies a semiconductor manufacturer description;

FIG. 3 is an exemplary diagram showing all instances of patterns satisfying the rule;

FIG. 4 is a flowchart of a second embodiment of a method in accordance with the present disclosure;

FIG. 5 is an exemplary diagram of a pattern of interest and a region of interest based on (x,y) locations; and

FIG. 6 is a block diagram of an embodiment of a system in accordance with the present disclosure.

### DETAILED DESCRIPTION OF THE DISCLOSURE

Although claimed subject matter will be described in terms of certain embodiments, other embodiments, including embodiments that do not provide all of the benefits and features set forth herein, are also within the scope of this disclosure. Various structural, logical, process step, and electronic changes may be made without departing from the scope of the disclosure. Accordingly, the scope of the disclosure is defined only by reference to the appended claims.

Embodiments of an automatic process of generating regions of interest for CDU measurement are disclosed. CDU can be an important aspect of new integrated circuit design and production quality control for semiconductor manufacturers because CDU can help ascertain optimal performance of a VLSI chip. As disclosed herein, regions of interest for CDU measurement can be generated based on a semiconductor manufacturer's description of the region of interest or an approximate location (e.g., coordinates). Embodiments of a two-step process of generating regions of interest for CDU measurement are disclosed. The regions of interest can be generated without measurement coordinates from the semiconductor manufacturer. Measurement coordinates are sensitive information because design information may be involved. Generating regions of interest can be determined using Standard Verification Rule Format (SVRF) scripting language, which can be used for VLSI layout manipulation. Tagging regions of interest can provide a large number of sites that are similar in design and can better enable statistical analysis because there may be billions of polygons in a layout. Choosing metrology sites based on a structured approach disclosed herein can contribute to a tighter process control and better yield management.

The need for CDU-related features on the electron beam review and inspection tools has increased for at least two reasons. First, critical dimension scanning electron microscopes (CDSEMs) generally have long move acquire measure (MAM) time. With the increasing volume of CDU data needed by semiconductor manufacturers for process control, the cost of ownership for CDSEMs is increasing. Second, quantitative sizing of captured defects is becoming preferable for some applications. This way, the size parameter enabled by CDU can be used as yet another quantitative attribute in the automated defect classification (ADC) attribute-space. This can enable a smarter defect separation based on specific dimension(s) of the defects of interest.

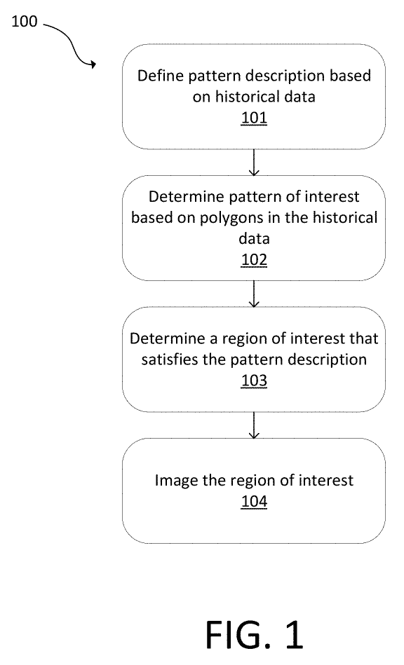

FIG. 1 is a flowchart of a method 100. The steps of the method 100 may be performed on or using a processor.

At 101, a pattern description is defined based on historical data. Historical data can include known failure cases based on technology ramp, such as tip-to-tip or tip-to-line. The pattern may be defined in vectorized image manipulation. The vectorized image manipulation scripting can help narrow potential regions of interest. The vectorized image manipulation scripting may involve previous historical methods and/or any new scripting needed to meet processing requirements.

SVRF scripting can be used. SVRF is an industry standard for polygon manipulation in the VLSI design files with GDS or OASIS formats. The scripting language is also used for design rule checks (DRC) and layout versus schematics (LVS) checks.

For example, a semiconductor manufacturer can provide a description of polygons where defects have been observed. This could be similar to the DRC rules, but may be more specific to provide fewer instances of the patterns compared to DRC. An algorithm can use SVRF language to describe the pattern, which can be searched for. A specific region of interest within a pattern of interest can be further marked. This region of interest may be where CD is to be measured.

DRC rules can be generic in nature. For example, a DRC rule may be all polygons in the gate region must have a width of 30 nm. DRC rules verify that all the polygons in the design are within manufacturing constraints. In the embodiments disclosed herein, patterns where CD should be measured are described. Thus, the patterns are typically specific and/or localized.

At 102, a pattern of interest is determined based on polygons in the historical data. In an instance, a pattern of interest is determined by a unique structure in a vicinity of the coordinates where a measurement is made. Vicinity can be defined by the defect location accuracy of the tool and may cover the context of the measurements described by a semiconductor manufacturer.

At 103, a region of interest on a semiconductor wafer is determined. The region of interest may satisfy the pattern description. The region of interest can be determined based on, for example, a description provided by a semiconductor manufacturer or historical data prone to marginalities. The region of interest satisfies the pattern description from 101. The region of interest may be exported to any format which can accommodate coordinates of a location. For example, the region of interest may be exported in a text file with coordinates of the locations that form the region of interest.

After the pattern description is defined, the region of interest is searched for in a smaller region. The pattern of interest, which is smaller than the image or entire wafer surface, can be used as a bounding box to look for regions of interest. The regions of interest may be, for example, a specific space, line width, or tip-to-tip distance.

The region of interest on the semiconductor wafer is imaged using a wafer inspection tool at 104. The wafer inspection tool may be a scanning electron microscope (SEM). Any region of interest images or measurements may be guided by the exported file from 102.

The wafer inspection tool and/or the processor also may search for instances of the pattern of interest on the semiconductor wafer.

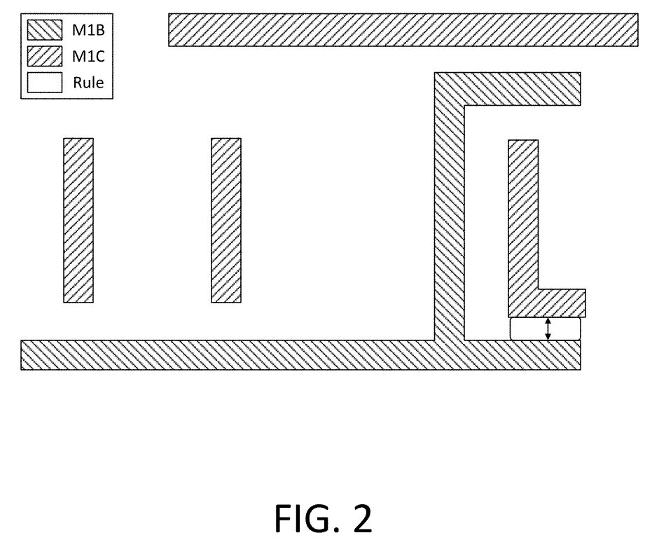

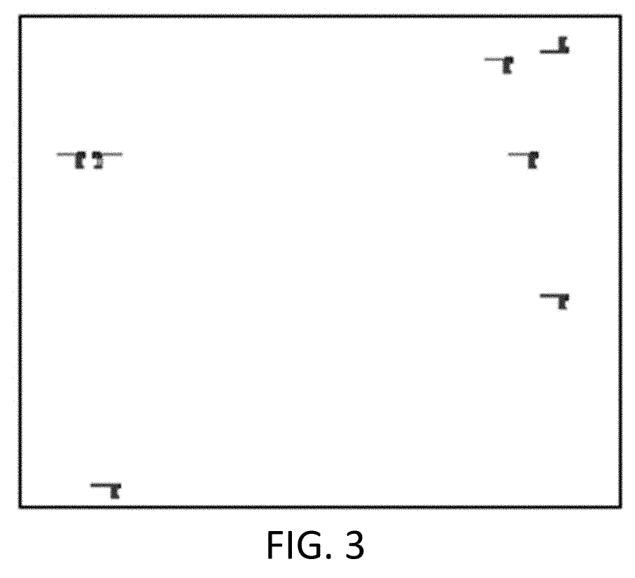

FIG. 2 is an exemplary diagram showing a pattern that satisfies a semiconductor manufacturer description. FIG. 3 is an exemplary diagram showing all instances of patterns satisfying the rule. For example, a semiconductor manufacturer wants to measure a minimum space of 19 nm between any two polygons from different masks. However, the semiconductor manufacturer cannot provide an accurate description of the pattern of interest in this example. Using the method 100, vectorized image manipulation is used to define the minimum space condition defined by the semiconductor manufacturer to determine the various patterns types that satisfy the rule. In the example of FIG. 2, the layer being considered is a triple patterned BEOL M1 layer. Upon execution of the rules, a pattern satisfies the criterion for the second and third patterning step. The second and third patterning steps are illustrated as M1B and M1C in FIG. 2.

The black box in FIG. 2 marked “Rule” with the dimension arrow satisfies the 19 nm condition. Seven instances of this pattern repeat across an area, as seen in FIG. 3. A derived design layer that contains these seven instances in various orientations in the layout can be created. This results in both the pattern of interest and region of interest where inspection needs to be performed. The wafer inspection tool can be used to make multiple images within this region for better accuracy of CD being measured.

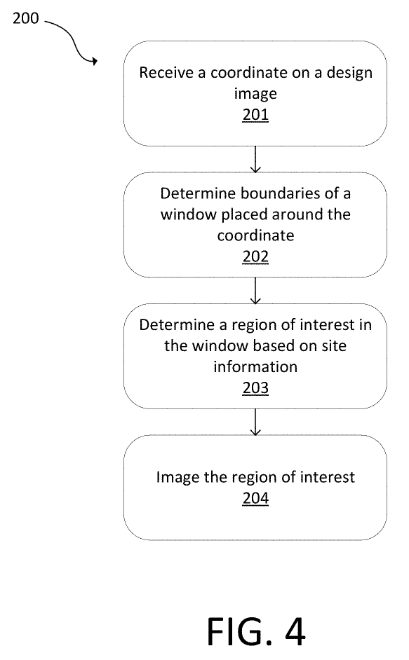

FIG. 4 is a flowchart of a second embodiment of a method 200. The steps of the method 200 may be performed on or using a processor.

At 201, a coordinate on a design image that includes a defect is received.

The coordinate on the design image may be converted to a coordinate in the wafer coordinate system. A coordinate transformation exercise that converts design coordinates to wafer coordinates may be performed.

At 202, boundaries of a window that is placed around the coordinate are determined. The window includes a pattern of interest. Thus, the pattern of interest can be defined by boundaries of the window. In an instance, a pattern of interest is determined by a unique structure in a vicinity of the coordinates where an inspection is made. Vicinity can be defined by the defect location accuracy (DLA) of the tool and may cover the context of the measurements described by a semiconductor manufacturer. The window can accommodate stage errors, tool errors, coordinate errors, LER, or other variables.

An algorithm can use a given coordinate and draw a box that corresponds to the dimensions of the pattern of interest. An operator also can select a box that is large enough based on the design and which is greater than the DLA, such as if case stage movement is involved.

Stage uncertainty of the tool may be known, which provides numbers related to the uncertainty (e.g., (dx,dy)). A region that may be greater than or equal to (dx,dy) around the measurement location can be chosen. This region can be location-based and (x,y) locations can be provided by the semiconductor manufacturer. This region also can be chosen by finding the areas where SVRF-based rule instances occurred and creating a box with (dx,dy) dimensions around it.

Designs are based on a design rule technology, such as 14 nm or 10 nm technology nodes. This can give an indication of the minimum polygon width and space between polygons. The design rule node number can represent a minimum half-pitch. For example, this minimum half-patch may be 0.5 (minimum width+minimum space). This provides information about how large the box may be.

For example, if a 10 nm design rule is used and features pertaining to those dimensions are measured, a box which is 4× or 5× the design rule may be selected to compensate for the DLA and also provide a surrounding context.

A rule-based search for the pattern of interest may be performed. The pattern of interest may be defined in vectorized image manipulation. The vectorized image manipulation scripting can help narrow down potential regions of interest.

At 203, a region of interest in the window is determined based on site information. Site information can be provided by a semiconductor manufacturer or can be based on historically-available critical structures. The region of interest can use any design scripting language (e.g., SVRF) to process vectorized image information based on inputs given by a semiconductor manufacturer. The region of interest may be exported to any format which can accommodate coordinates of a location. For example, the region of interest may be exported in a text file with coordinates of the locations that form the region of interest.

After the pattern description is defined, the region of interest is searched for in a smaller region. The pattern of interest, which is smaller than the image or entire wafer surface, can be used as a bounding box to look for regions of interest. The regions of interest may be, for example, a specific space, line width, or tip-to-tip distance.

The region of interest on the semiconductor wafer is imaged using a wafer inspection tool at 204. The wafer inspection tool may be an SEM. The region of interest images or inspection may be guided by the exported file from 203.

The wafer inspection tool and/or the processor also may search for instances of the pattern of interest on the semiconductor wafer.

Method 200 can define patterns of interest based on polygons interacting with a measurement site, which can be relatively easy to perform with vectorized image manipulation. However, if the polygons interacting with the measurement site are large, then the pattern of interest may be larger than expected.

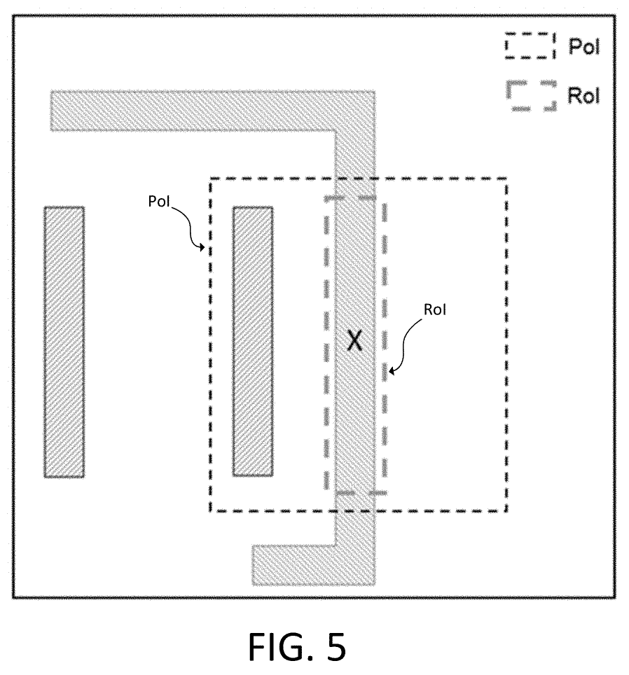

FIG. 5 is an exemplary diagram of a pattern of interest and a region of interest based on (x,y) locations. The method 200 is applied in FIG. 5. The method 200 may only involve polygons in the pattern of interest that are close to the measurement site. The method 200 may not contain all the polygons in the vicinity of the measurement site.

In an example, the coordinate system provided by the semiconductor manufacturer is converted to a design coordinate system. The (x,y) information and windowing technique are used to clip out a portion of the pattern of interest. DLA and other uncertainties caused by the coordinate translation are included in this clipping function.

The measurement site is then defined based on the in specific information provided by the semiconductor manufacturer. In the example of FIG. 5, the semiconductor manufacturer may want to measure CD on the polygon from the second patterning step (M1B with the X in the pattern of interest (PoI)). A region of interest box (RoI) is defined on that polygon for one or multiple measurements.

The method 200 may provide all the polygons that define the pattern of interest, but the clipping may render the pattern of interest incomplete. This can occur if the window is not drawn appropriately or is too small.

In the method 100 or the method 200, the region of interest may be disposed in the pattern of interest.

The method 100 or method 200 can include a feedback loop. The feedback loop can use, for example, CD measurements to fix drifts in a tool.

Some or all of the steps of the method 100 or method 200 can be automated. This can increase throughput.

The embodiments disclosed herein can provide a larger set of patterns of interest than would occur by using a few predefined sites. In a design file, there can be numerous sites which may be critical and need to be monitored using CDU. Using a few defined sites may not give the details about the dimensions across the wafer. Using vectorized image processing can generate a list of all critical sites across the wafer where the CD can be measured and monitored.

The embodiments disclosed herein can improve the odds of detecting newer failure modes or hotspots earlier in the process flow. Generic rule-based search algorithms may be dependent on process failures and device testing results that occur later in a manufacturing process flow.

Embodiments of the method 100 and method 200 can provide a framework for automatic generation of patterns of interest and regions of interest for CDU measurements. Since the process involves statistics and metrology, design-based measurements can provide the reference for the entire process. Once such patterns of interest and/or regions of interest are identified using vectorized image manipulation, these can be imported into any electron beam-based review or inspection system in the form of a exported file and/or site list and imaged (offline or inline on the tool). The increasing adoption of design-enabled features on the electron beam-based review or inspection system can help visit the identified sites with increased spatial accuracy and even extract polygon/electrical properties along with CDU measurements on the imaged structures. This can provide further integration of CDU, polygon, and electrical level data for defect detection/classification and intelligent process control techniques for APC because design information is of multiple types. For example, the design information may be from low level to high level (e.g., electrical conductivity information). Using embodiments disclosed herein, design information can be used to be able to better measure sites of higher criticality. This information can be fed back into the process for enhanced yield and/or performance.

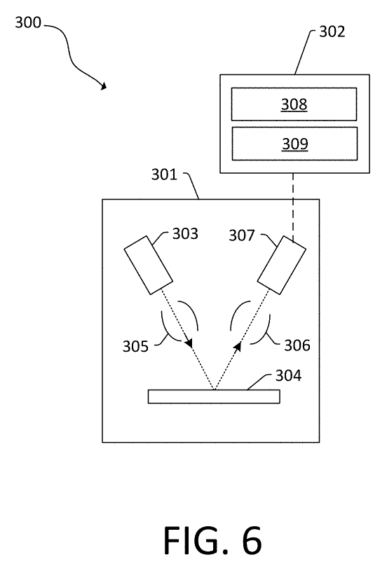

FIG. 6 is a block diagram of an embodiment of a system 300. The system 300 includes a wafer inspection tool (which includes the electron column 301) configured to generate images of a wafer 304.

The wafer inspection tool includes an output acquisition subsystem that includes at least an energy source and a detector. The output acquisition subsystem may be an electron beam-based output acquisition subsystem. For example, in one embodiment, the energy directed to the wafer 304 includes electrons, and the energy detected from the wafer 304 includes electrons. In this manner, the energy source may be an electron beam source. In one such embodiment shown in FIG. 6, the output acquisition subsystem includes electron column 301, which is coupled to computer subsystem 302. A chuck (not illustrated) may hold the wafer 304.

As also shown in FIG. 6, the electron column 301 includes an electron beam source 303 configured to generate electrons that are focused to wafer 304 by one or more elements 305. The electron beam source 303 may include, for example, a cathode source or emitter tip. The one or more elements 305 may include, for example, a gun lens, an anode, a beam limiting aperture, a gate valve, a beam current selection aperture, an objective lens, and a scanning subsystem, all of which may include any such suitable elements known in the art.

Electrons returned from the wafer 304 (e.g., secondary electrons) may be focused by one or more elements 306 to detector 307. One or more elements 306 may include, for example, a scanning subsystem, which may be the same scanning subsystem included in element(s) 305.

The electron column also may include any other suitable elements known in the art.

Although the electron column 301 is shown in FIG. 6 as being configured such that the electrons are directed to the wafer 304 at an oblique angle of incidence and are scattered from the wafer 304 at another oblique angle, the electron beam may be directed to and scattered from the wafer 304 at any suitable angles. In addition, the electron beam-based output acquisition subsystem may be configured to use multiple modes to generate images of the wafer 304 (e.g., with different illumination angles, collection angles, etc.). The multiple modes of the electron beam-based output acquisition subsystem may be different in any image generation parameters of the output acquisition subsystem.

Computer subsystem 302 may be coupled to detector 307 as described above. The detector 307 may detect electrons returned from the surface of the wafer 304 thereby forming electron beam images of the wafer 304. The electron beam images may include any suitable electron beam images. Computer subsystem 302 may be configured to perform any of the functions described herein using the output of the detector 307 and/or the electron beam images. Computer subsystem 302 may be configured to perform any additional step(s) described herein. A system 300 that includes the output acquisition subsystem shown in FIG. 6 may be further configured as described herein.

It is noted that FIG. 6 is provided herein to generally illustrate a configuration of an electron beam-based output acquisition subsystem that may be used in the embodiments described herein. The electron beam-based output acquisition subsystem configuration described herein may be altered to optimize the performance of the output acquisition subsystem as is normally performed when designing a commercial output acquisition system. In addition, the systems described herein may be implemented using an existing system (e.g., by adding functionality described herein to an existing system). For some such systems, the methods described herein may be provided as optional functionality of the system (e.g., in addition to other functionality of the system). Alternatively, the system described herein may be designed as a completely new system.

Although the output acquisition subsystem is described above as being an electron beam-based output acquisition subsystem, the output acquisition subsystem may be an ion beam-based output acquisition subsystem. Such an output acquisition subsystem may be configured as shown in FIG. 6 except that the electron beam source may be replaced with any suitable ion beam source known in the art. In addition, the output acquisition subsystem may be any other suitable ion beam-based output acquisition subsystem such as those included in commercially available focused ion beam (FIB) systems, helium ion microscopy (HIM) systems, and secondary ion mass spectroscopy (SIMS) systems.

The computer subsystem 302 includes a processor 308 and an electronic data storage unit 309. The processor 308 may include a microprocessor, a microcontroller, or other devices. The processor 308 and/or the electronic data storage unit 309 optionally may be in electronic communication with a wafer inspection tool or a wafer review tool (not illustrated) to receive additional information.

The computer subsystem 302 may be coupled to the components of the system 300 in any suitable manner (e.g., via one or more transmission media, which may include wired and/or wireless transmission media) such that the processor 308 can receive output. The processor 308 may be configured to perform a number of functions using the output. The wafer inspection tool can receive instructions or other information from the processor 308. The processor 308 and/or the electronic data storage unit 309 optionally may be in electronic communication with another wafer inspection tool, a wafer metrology tool, or a wafer review tool (not illustrated) to receive additional information or send instructions.

The processor 308 is in electronic communication with the wafer inspection tool, such as the detector 307. The processor 308 may be configured to process images generated using measurements from the detector 307. For example, the processor may perform embodiments of the method 100 or method 200.

The computer subsystem 302, other system(s), or other subsystem(s) described herein may be part of various systems, including a personal computer system, image computer, mainframe computer system, workstation, network appliance, internet appliance, or other device. The subsystem(s) or system(s) may also include any suitable processor known in the art, such as a parallel processor. In addition, the subsystem(s) or system(s) may include a platform with high-speed processing and software, either as a standalone or a networked tool.

The processor 308 and electronic data storage unit 309 may be disposed in or otherwise part of the system 300 or another device. In an example, the processor 308 and electronic data storage unit 309 may be part of a standalone control unit or in a centralized quality control unit. Multiple processors 308 or electronic data storage units 309 may be used.

The processor 308 may be implemented in practice by any combination of hardware, software, and firmware. Also, its functions as described herein may be performed by one unit, or divided up among different components, each of which may be implemented in turn by any combination of hardware, software and firmware. Program code or instructions for the processor 308 to implement various methods and functions may be stored in readable storage media, such as a memory in the electronic data storage unit 309 or other memory.

If the system 300 includes more than one computer subsystem 302, then the different subsystems may be coupled to each other such that images, data, information, instructions, etc. can be sent between the subsystems. For example, one subsystem may be coupled to additional subsystem(s) by any suitable transmission media, which may include any suitable wired and/or wireless transmission media known in the art. Two or more of such subsystems may also be effectively coupled by a shared computer-readable storage medium (not shown).

The processor 308 may be configured to perform a number of functions using the output of the system 300 or other output. For instance, the processor 308 may be configured to send the output to an electronic data storage unit 309 or another storage medium. The processor 308 may be further configured as described herein.

The processor 308 or computer subsystem 302 may be part of a defect review system, an inspection system, a metrology system, or some other type of system. Thus, the embodiments disclosed herein describe some configurations that can be tailored in a number of manners for systems having different capabilities that are more or less suitable for different applications.

If the system includes more than one subsystem, then the different subsystems may be coupled to each other such that images, data, information, instructions, etc. can be sent between the subsystems. For example, one subsystem may be coupled to additional subsystem(s) by any suitable transmission media, which may include any suitable wired and/or wireless transmission media known in the art. Two or more of such subsystems may also be effectively coupled by a shared computer-readable storage medium (not shown).

The processor 308 may be configured according to any of the embodiments described herein. The processor 308 also may be configured to perform other functions or additional steps using the output of the system 300 or using images or data from other sources.

The processor 308 may be communicatively coupled to any of the various components or sub-systems of system 300 in any manner known in the art. Moreover, the processor 308 may be configured to receive and/or acquire data or information from other systems (e.g., inspection results from an inspection system such as a review tool, a remote database including design data and the like) by a transmission medium that may include wired and/or wireless portions. In this manner, the transmission medium may serve as a data link between the processor 308 and other subsystems of the system 300 or systems external to system 300.

Various steps, functions, and/or operations of system 300 and the methods disclosed herein are carried out by one or more of the following: electronic circuits, logic gates, multiplexers, programmable logic devices, ASICs, analog or digital controls/switches, microcontrollers, or computing systems. Program instructions implementing methods such as those described herein may be transmitted over or stored on carrier medium. The carrier medium may include a storage medium such as a read-only memory, a random access memory, a magnetic or optical disk, a non-volatile memory, a solid state memory, a magnetic tape, and the like. A carrier medium may include a transmission medium such as a wire, cable, or wireless transmission link. For instance, the various steps described throughout the present disclosure may be carried out by a single processor 308 (or computer subsystem 302) or, alternatively, multiple processor 308 (or multiple computer subsystems 202). Moreover, different sub-systems of the system 300 may include one or more computing or logic systems. Therefore, the above description should not be interpreted as a limitation on the present disclosure but merely an illustration.

An additional embodiment relates to a non-transitory computer-readable medium storing program instructions executable on a processor. In particular, a processor, such as the processor 308, can be coupled to a memory in an electronic data storage medium with non-transitory computer-readable medium, such as the electronic data storage medium 309, that includes executable program instructions. The computer-implemented method may include any step(s) of any method(s) described herein. For example, processor 308 may be programmed to perform some or all of the steps of method 100 or method 200. The memory in the electronic data storage medium 309 may be a storage medium such as a magnetic or optical disk, a magnetic tape, or any other suitable non-transitory computer-readable medium known in the art.

The program instructions may be implemented in any of various ways, including procedure-based techniques, component-based techniques, and/or object-oriented techniques, among others. For example, the program instructions may be implemented using ActiveX controls, C++ objects, JavaBeans, Microsoft Foundation Classes (MFC), Streaming SIMD Extension (SSE), or other technologies or methodologies, as desired.

In an embodiment, one or more programs are included on a non-transitory computer-readable storage medium, such as the electronic data storage medium 309. The one or more programs are for executing steps on one or more computing devices. For example, the steps can include determining both a pattern of interest and a region of interest on the semiconductor wafer and sending instructions to the wafer inspection tool to measure the region of interest on the semiconductor wafer. The pattern of interest is defined in vectorized image manipulation scripting. In another example, the steps can include defining a pattern description based on historical data that includes failure cases; defining the region of interest such that the region of interest satisfies the pattern description; and determining the pattern of interest based on polygons in the region of interest. In another example, the steps can include receiving a coordinate on a design image for the semiconductor wafer; determining boundaries of a window that is placed around the coordinate; and determining a region of interest in the window based on site information. The region of interest is defined using a design scripting language. The window includes the pattern of interest. In either example, a wafer inspection tool can image and/or provide measurements of features in the region of interest.

As used herein, the term “wafer” generally refers to substrates formed of a semiconductor or non-semiconductor material. Examples of such a semiconductor or non-semiconductor material include, but are not limited to, monocrystalline silicon, gallium nitride, gallium arsenide, indium phosphide, sapphire, and glass. Such substrates may be commonly found and/or processed in semiconductor fabrication facilities.

A wafer may include one or more layers formed upon a substrate. For example, such layers may include, but are not limited to, a photoresist, a dielectric material, a conductive material, and a semiconductive material. Many different types of such layers are known in the art, and the term wafer as used herein is intended to encompass a wafer including all types of such layers.

One or more layers formed on a wafer may be patterned or unpatterned. For example, a wafer may include a plurality of dies, each having repeatable patterned features or periodic structures. Formation and processing of such layers of material may ultimately result in completed devices. Many different types of devices may be formed on a wafer, and the term wafer as used herein is intended to encompass a wafer on which any type of device known in the art is being fabricated.

Other types of wafers also may be used. For example, the wafer may be used to manufacture LEDs, solar cells, magnetic discs, flat panels, or polished plates. Defects on other objects also may be classified using techniques and systems disclosed herein.

Each of the steps of the method may be performed as described herein. The methods also may include any other step(s) that can be performed by the processor and/or computer subsystem(s) or system(s) described herein. The steps can be performed by one or more computer systems, which may be configured according to any of the embodiments described herein. In addition, the methods described above may be performed by any of the system embodiments described herein.

Although the present disclosure has been described with respect to one or more particular embodiments, it will be understood that other embodiments of the present disclosure may be made without departing from the scope of the present disclosure. Hence, the present disclosure is deemed limited only by the appended claims and the reasonable interpretation thereof.

What is claimed is:

1. A method comprising:
defining, using a processor, a pattern description based on historical data, wherein the historical data includes failure cases, and wherein the pattern is defined in vectorized image manipulation scripting;
determining, using the processor, a pattern of interest on a semiconductor wafer based on polygons in the historical data;
determining, using the processor, a region of interest disposed in the pattern of interest on the semiconductor wafer that satisfies the pattern description; and
imaging the region of interest on the semiconductor wafer using a wafer inspection tool.

2. The method of claim 1, wherein the pattern of interest is defined in Standard Verification Rule Format.

3. The method of claim 1, wherein the wafer inspection tool is a scanning electron microscope.

4. The method of claim 1, further comprising searching for instances of the pattern of interest on the semiconductor wafer.

5. A computer program product comprising a non-transitory computer readable storage medium having a computer readable program embodied therewith, the computer readable program configured to carry out the method of claim 1.

6. A method comprising:
receiving, at a processor, a coordinate on a design image that includes a defect;
determining, using the processor, boundaries of a window that is placed around the coordinate, wherein the window includes a pattern of interest, wherein the pattern of interest is defined in vectorized image manipulation scripting;
determining, using the processor, a region of interest in the window based on site information, wherein the region of interest uses a design scripting language, and wherein the region of interest is disposed in the pattern of interest; and
imaging the region of interest on the semiconductor wafer using a wafer inspection tool.

7. The method of claim 6, further comprising converting the coordinate in the design image to a coordinate in a wafer coordinate system.

8. The method of claim 6, wherein the pattern of interest is defined by the boundaries of the window.

9. The method of claim 6, wherein the wafer inspection tool is a scanning electron microscope.

10. The method of claim 6, further comprising, searching for instances of the pattern of interest on the semiconductor wafer.

11. A computer program product comprising a non-transitory computer readable storage medium having a computer readable program embodied therewith, the computer readable program configured to carry out the method of claim 6.

12. A system comprising:
a wafer inspection tool configured to generate images of a wafer, the wafer inspection tool including:
an energy source that directs energy at a surface of a semiconductor wafer; and
a detector; and
a processor in electronic communication with the wafer inspection tool, wherein the processor is configured to determine both a pattern of interest and a region of interest on the semiconductor wafer, wherein the region of interest disposed in the pattern of interest on the wafer, wherein the pattern of interest is defined in vectorized image manipulation scripting, and wherein the processor is configured to send instructions to the wafer inspection tool to image the region of interest on the semiconductor wafer.

13. The system of claim 12, wherein the wafer inspection tool is a scanning electron microscope.

14. The system of claim 12, wherein the processor is configured to:
define a pattern description based on historical data, wherein the historical data includes failure cases;
determine the pattern of interest based on polygons in the historical data; and
determine the region of interest such that the region of interest satisfies the pattern description.

15. The system of claim 12, wherein the processor is configured to:
receive a coordinate on a design image for the semiconductor wafer;
determine boundaries of a window that is placed around the coordinate, wherein the window includes the pattern of interest; and
determine a region of interest in the window based on site information, wherein the region of interest is defined using a design scripting language.

16. The system of claim 15, wherein the processor is further configured to convert the coordinate in the design image to a coordinate in a wafer coordinate system.

17. The system of claim 15, wherein the pattern of interest is defined by the boundaries of the window.

18. The system of claim 12, wherein the processor is further configured to find instances of the pattern of interest on the semiconductor wafer.
